(19) United States
(12) Patent Application Publication
(10) Pub. No.: US 2025/0046633 A1
(43) Pub. Date: Feb. 6, 2025

(54) SYSTEMS AND METHODS FOR ACCURATE DETERMINATION OF SEMICONDUCTOR WAFER TEMPERATURE

(71) Applicant: Taiwan Semiconductor Manufacturing Company, Ltd., Hsinchu (TW)

(72) Inventors: Chung Hsien Liao, Hsinchu (TW); Po Wen Yang, Miaoli County (TW); Jui-Mu Cho, Hsinchu (TW); Chien-Fang Lin, Tainan (TW)

(21) Appl. No.: 18/363,699

(22) Filed: Aug. 1, 2023

(51) Int. Cl. H01L 21/67

(52) U.S. Cl. CPC H01L 21/67248; H01L 21/67109

(57) ABSTRACT

A semiconductor processing system is provided. The semiconductor processing system includes a first chamber arranged to perform a first semiconductor process; a second chamber arranged to perform a second semiconductor process; a cooling chamber having a pedestal; and a plurality of non-contact temperature sensors mounted in the cooling chamber, and arranged to measure a temperature of a wafer disposed on the pedestal. In one aspect, the first chamber is arranged to transfer the wafer to the cooling chamber upon completion of the first semiconductor process in the first chamber. In another aspect, the cooling chamber is arranged to measure the temperature of the wafer in the cooling chamber and arranged to transfer the wafer to the second chamber when the temperature of wafer is at a target temperature, or pause processing of the wafer when the temperature of the wafer is not at the target temperature.

### FIELD

Embodiments of the present disclosure relate generally to semiconductor processing, and more particularly to systems and methods for accurate determination of wafer temperature.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area.

While some integrated device manufacturers (IDMs) design and manufacture integrated circuits (IC) themselves, fabless semiconductor companies outsource semiconductor fabrication to semiconductor fabrication plants or foundries. Semiconductor fabrication consists of a series of processes in which a device structure is manufactured by applying a series of layers onto a substrate. This involves the deposition and removal of various dielectric, semiconductor, and metal layers. The areas of the layer that are to be deposited or removed are controlled through photolithography. Each deposition and removal process is generally followed by cleaning as well as inspection steps. Therefore, both IDMs and foundries rely on numerous semiconductor equipment and semiconductor fabrication materials, often provided by vendors. There is always a need for customizing or improving those semiconductor equipment and semiconductor fabrication materials, which results in more flexibility, reliability, and cost-effectiveness.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A shows a plan view illustrating a semiconductor processing system with non-contact temperature sensors, in accordance with some embodiments.

FIG. 1B shows a schematic diagram illustrating the non-contact temperature sensors of FIG. 1A, in accordance with some embodiments.

FIG. 2 is a flowchart diagram illustrating an example method of operating the semiconductor processing system with non-contact temperature sensors, in accordance with some embodiments.

FIG. 3 is a flowchart diagram illustrating an example method of operating the semiconductor processing system in-situ in the processing chamber with non-contact temperature sensors, in accordance with some embodiments.

FIG. 4 is a flowchart diagram illustrating an example method of operating the semiconductor processing system in-situ in the processing chamber after the completion of processing with non-contact temperature sensors, in accordance with some embodiments.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

A multi-chamber semiconductor processing system is commonly used for semiconductor processing, which includes multiple processes such as physical vapor deposition (PVD), atomic layer deposition (ALD), and various kinds of chemical vapor deposition (CVD) (e.g., metal-organic chemical vapor deposition (MOCVD), atmospheric-pressure CVD (APCVD), low-pressure CVD (LPCVD), ultra-high-vacuum CVD (UHVCVD)). Each process corresponds to a chamber in the multi-chamber semiconductor processing system, and each chamber may have a different target temperature. If the actual temperature deviates from the target temperature, the grain size of the film formed may deviate from the target grain size. In addition, the properties of the film formed may be degraded.

Transfer robots are typically used in a multi-chamber semiconductor processing system to transfer the wafer from one chamber to another according to the process log. In some examples, one transfer robot is used. In other examples, two or more transfer robots are used. When the wafer is transferred by the transfer robot from a first chamber having a first target temperature to a second chamber having a second target temperature, the process to be conducted in the second chamber cannot begin until the temperature of the wafer ramps up precisely to the second target temperature. Therefore, an accurate monitoring of a wafer temperature is needed to ensure process quality. If the process to be conducted in the second chamber starts without the wafer being at the target temperature, the grain size of the film formed may deviate, and the properties of the film formed may be degraded, as explained above. It should be understood that the above embodiments or examples are not intended to be limiting, and the transfer robot may have various forms and designs. It should also be understood that although one transfer robot is discussed above, more than one transfer robot can be accommodated in the transfer chamber.

A semiconductor wafer may be processed by subjecting the wafer to various process steps, such as, but not limited to, physical vapor deposition (PVD), and various kinds of chemical vapor deposition (CVD) (e.g., metal-organic chemical vapor deposition (MOCVD), atmospheric-pressure CVD (APCVD), low-pressure CVD (LPCVD), ultra-high-vacuum CVD (UHVCVD)). Accurate monitoring of temperature of the wafer in a semiconductor processing system is used in order to control defects in the semiconductor wafer. Abnormal actual temperature of the semiconductor wafer may cause defects, for example, if the actual temperature deviates from the target temperature, the grain size of a film formed may deviate from the target grain size. In addition, the properties of the film formed may be degraded, as explained above.

Current approaches for semiconductor wafer temperature measurement can include thermocouples and/or pyrometry. Thermocouples can be easy to use, however their reliability and accuracy can be questionable. They are accurate when the semiconductor wafer is in thermal equilibrium with its surroundings and the thermocouple is embedded in that environment. When this condition is not met, the thermocouple reading might be very far from the true semiconductor wafer temperature. For example, in PVD, the thermocouple embedded in the heated chuck, gives a temperature reading which may resemble that of the wafer in a fairly reasonable manner, but only before the process actually begins. When the plasma deposition process actually starts, the wafer temperature changes significantly, but the thermocouple reading is hardly affected.

Current approaches may include other techniques such as optical pyrometry. A pyrometer deduces the semiconductor wafer's temperature from the intensity of the radiation emitted by the wafer. The relation between the intensity of the radiation and the wafer temperature is given by Plank's law which shows that the radiation emitted by any object is a function of its temperature, emissivity and the wavelength of measurement. In current approaches, a common way of using a pyrometer is to collect the radiation from the wafer using a quartz or sapphire rod. While the use of pyrometry techniques can be superior to the use of thermocouples, there can be some problems of inaccuracy in the actual processing environment, which cannot be ignored.

In current approaches, wafer temperature is measured after the wafer processing has been completed. For example, when a semiconductor wafer is found to have defects caused by abnormal process temperature, after the completion of the PVD and/or CVD process step, a monitor wafer (also referred to a thermocouple wafer) may be processed through the PVD and/or CVD chamber in order to determine the temperature of the chamber. The monitor wafer can be placed inside the chamber on a pedestal and the pedestal can be heated to a standard temperature. A standard recipe (also referred to a golden recipe) may be run on the monitor wafer.

When a semiconductor wafer is found to have defects caused by abnormal process temperature, details of the thermocouple wafer (TC) measurement action may include the steps of: venting the processing chamber and removing the cover ring; placing a TC wafer on an upper lift position and pumping down the chamber; set the heater to standard temperature; Setup connection with the TC wafer; manually open backside final valve and then close it; place the processing chamber back on and then run a golden recipe; check TC wafer data, and then fine tune the heater temperature recipe to match the TC target spec.

Subsequently, defects of the monitor wafer are measured and compared to target values. If the monitor wafer defects are higher than the target values, factors for control of the temperature of the pedestal may be modified accordingly. Current approaches can cause delay time due to the processing of the monitor wafer and adjusting of the parameters of the pedestal/chamber temperature. The delay time may occur in every few batches of wafers and can collectively result in a loss in productivity of the semiconductor processing system. The loss in productivity becomes a more significant issue in situations like a global semiconductor shortage.

In accordance with some aspects of the disclosure, systems and methods for accurate determination of semiconductor wafer temperature are provided. In some embodiments, a semiconductor processing system can have a first chamber, a cooling chamber and a second chamber. Non-contact temperature sensors may be mounted in the cooling chamber. Upon completion of processing in the first chamber, a wafer may be transferred to the cooling chamber, where the non-contact temperature sensors are arranged to measure a temperature of the wafer in real time. If the measured temperature is at a target temperature, the wafer can be transferred to the second chamber for further processing. If the measure temperature is not at the target temperature, the processing of the wafer may be paused.

In this way, wafer temperature can be monitored accurately, thereby reducing wafer defects. Further, the delay time due to running a monitor wafer through the semiconductor processing system after the completion of processing of the wafers can be significantly reduced or completely avoided, thereby enhancing the productivity of the semiconductor processing system. In various embodiments, the temperature sensors may be mounted near a transfer path of the wafer from the first chamber to the cooling chamber and arranged to measure the temperature of the wafer in the transfer path.

In some embodiments, the non-contact temperature sensors can be configured to measure the temperature of the wafer at various locations on the wafer, such as in the center, edge and various locations between the center and the edge on the wafer in order to provide accurate temperature of the wafer. In this way, an accurate edge-to-center temperature profile of the semiconductor wafer can be measured. Furthermore, excessive temperature gradients can be detected to prevent misprocessing of the semiconductor wafer.

In various embodiments, non-contact temperature sensors may be added to the first processing chamber of the semiconductor processing system in order to monitor wafer temperature in situ while the wafer is in the first chamber. The temperature sensors can monitor the semiconductor wafer temperature during the processing and upon completion of the first semiconductor processing of the wafer in the first chamber. In some embodiments, the non-contact temperature sensors may be infrared temperature sensors. In various embodiments, the non-contact temperature sensors may be ultrasonic temperature sensors. In some embodiments, the non-contact temperature sensors may include infrared temperature sensors as well as ultrasonic temperature sensors.

In various embodiments, non-contact temperature sensors can include optical pyrometers, radiation thermometers, thermal imagers, and fiber optic sensors. Radiation thermometers can measure the radiation emitted from a semiconductor wafer. Thermal imagers can calculate wafer temperature in a two-dimensional space rather than measuring temperature based on a given point on the surface of an object. Thermocouples can have an extensive temperature range, and are self-powered. However, they may have relatively low accuracy. Radiation thermometers can be accurate, repeatable, and have long-term stability. However, their response may be relatively slow, and the temperature range they can detect may be limited. Radiation thermometers are also not as cost-efficient as other sensors due to their high expense.

Optical pyrometers can measure high temperatures with high accuracy. However, they can be expensive, and accuracy can be affected by thermal background radiation, dust, and smoke. Fiber-optic temperature sensors are variants of radiation thermometers. Radiation is sensed by an active sensing device, and the system processes and converts it into a temperature readout. Optical pyrometers have an optical system and a detector, measuring temperatures that are too bright to see with the naked eye. The optical system focuses the radiation onto the detector, providing the temperature measurement. Fiber-optic temperature sensors are immune from nearby radiation and are accurate with a fast response time, but can be expensive, and measurement systems can be complex to develop.

Temperature is a critical process control parameter during semiconductor processing such as in CVD processing. In some embodiments, non-contact temperature sensors are selected such that even when the plasma emits infrared energy at very specific wavelengths, accurate detection of the semiconductor wafer temperature can be performed. For example, it is can be critical to select a pyrometer with a wavelength that can view through the plasma so that consistent wafer temperature readings can be achieved.

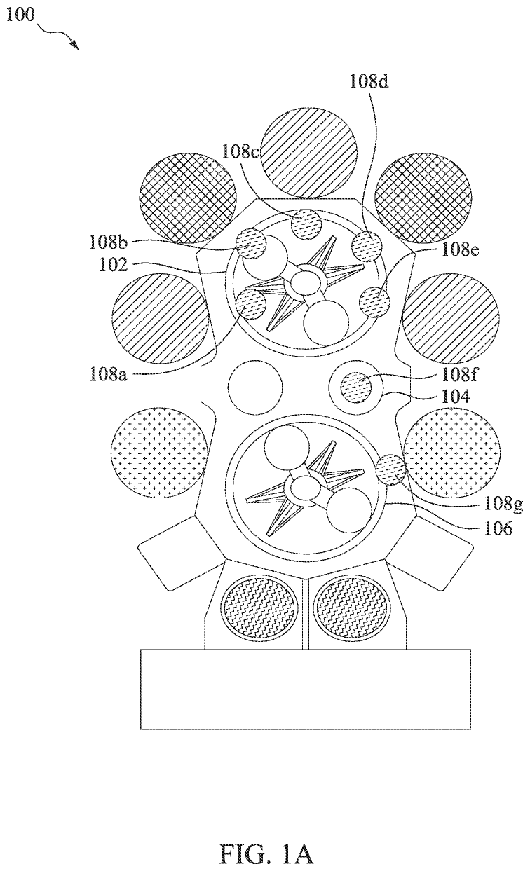

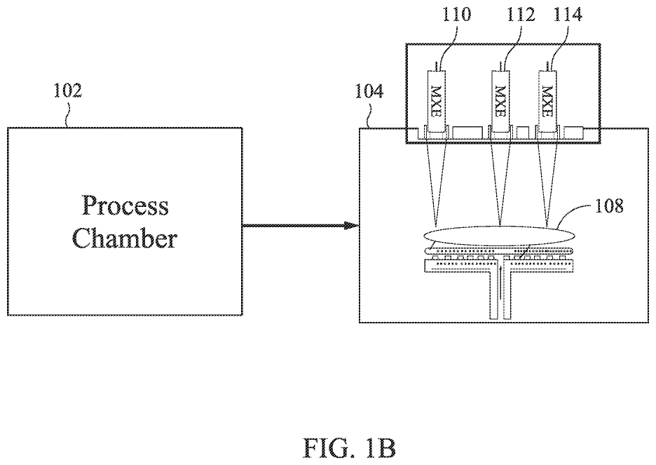

FIG. 1A shows a plan view illustrating a semiconductor processing system 100 with non-contact temperature sensors, in accordance with some embodiments. FIG. 1B shows a schematic diagram illustrating the non-contact temperature sensors of FIG. 1A, in accordance with some embodiments. The semiconductor processing system 100 can include a first process chamber 102, a cooling chamber 104 and a second process chamber 106. The semiconductor processing system 100 can be configured to process a wafer 108 through a wafer transfer path that includes positions 108a-108g within the semiconductor processing system 100. The wafer 108 may be processed in the first process chamber 102 according to a first semiconductor process and transferred to the cooling chamber 104 (position 108f), where the temperature of the wafer can be measured. The wafer may then be transferred to the second process chamber 106 (position 108g) where the wafer can be processed according to a second semiconductor process. It should be understood that although a cooling chamber 104 and two process chambers 102 and 106 are illustrated in FIGS. 1A and 1B, this is not intended to be limiting. In other examples, other numbers (e.g., three, four, five, etc.) of process chambers and other numbers (e.g., two, three, etc.) of cooling chambers may be employed.

As shown in FIG. 1B, the cooling chamber 104 can include a first non-contact temperature sensor 110, a second non-contact temperature sensor 112 and a third non-contact temperature sensor 114. The cooling chamber 104 can also include a pedestal 116 that is arranged such that a semiconductor wafer 108 can be placed on the pedestal 116. The first non-contact temperature sensor 110 can be configured to sense a first temperature at an edge region of the wafer 108. The second non-contact temperature sensor 112 can be configured to sense a second temperature at in a center region of the wafer 108. The third non-contact temperature sensor 114 can be configured to sense a third temperature in a region between the center and edge of the wafer 108. In some embodiments, the cooling chamber 104 may include a plurality of non-contact temperature sensors, where the plurality of non-contact temperature sensors may include four or more temperature sensors arranged to measure temperature at various locations of the wafer.

The non-contact temperature sensors can be infrared-based, or ultrasound-based. Further examples of these sensors may include, but are not limited to, pyrometers, photodiodes, spectrometers, high or low speed cameras operating in visible, ultraviolet, or IR spectral ranges, etc. It should be understood that although the transfer and temperature measurement of one wafer 108 is described above as an example, that several wafers can be transferred to the cooling chamber 104 and have their temperature measured.

In some embodiments, the first process chamber 102 may be arranged to house a first non-contact temperature sensor, a the second non-contact temperature sensor and a the third non-contact temperature sensor. It should be understood that use of three temperature sensors is not intended to be limiting. In other examples, other numbers (e.g., four, five, etc.) of temperature sensors can be arranged inside the process chamber. In this embodiment, the first non-contact temperature sensor can be configured to sense a first temperature at an edge region of the wafer 108, the second non-contact temperature sensor can be configured to sense a second temperature at in a center region of the wafer 108 and the third non-contact temperature sensor can be configured to sense a third temperature in a region between the center and edge of the wafer 108. The wafer temperature can be monitored in the first process chamber in situ during the semiconductor processing. In some embodiments, the wafer temperature can be monitored upon completion of the semiconductor processing in the first chamber.

In some embodiments, the second process chamber 106 may be arranged to house the non-contact temperature sensors. The non-contact temperature sensors can be arranged to measure the wafer temperature at an edge region of the wafer, in a center region of the wafer and in a region between the center and edge of the wafer. The wafer temperature can be monitored in the second process chamber in situ during the semiconductor processing. In some embodiments, the wafer temperature can be monitored upon completion of the semiconductor processing in the second chamber.

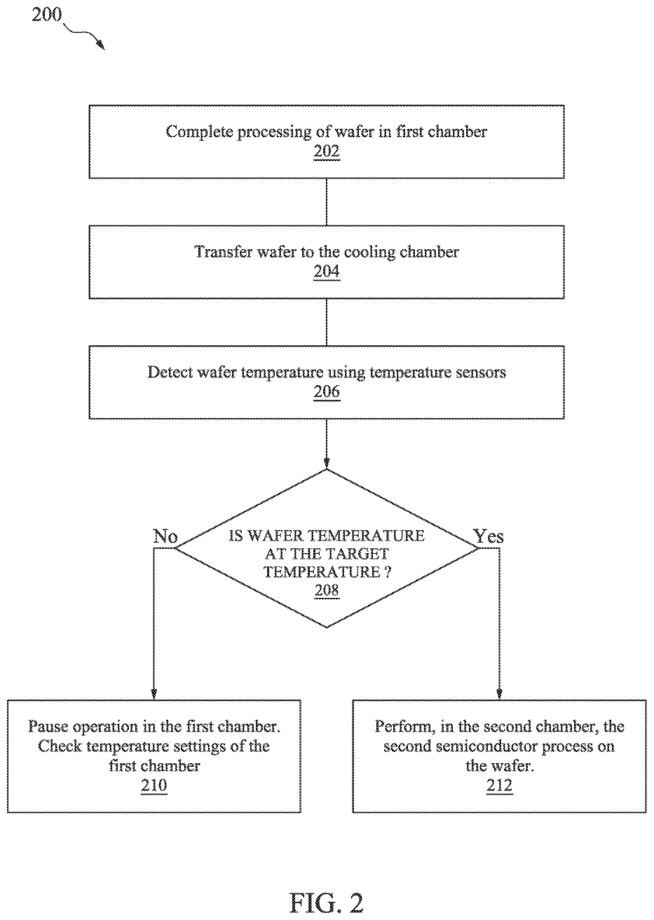

FIG. 2 is a flowchart diagram illustrating an example method 200 in accordance with some embodiments. In the example shown in FIG. 2, the method 200 includes operations 202, 204, 206, 208, 210 and 212. Additional operations may be performed. Also, it should be understood that the sequence of the various operations discussed above with reference to FIG. 2 is provided for illustrative purposes, and as such, other embodiments may utilize different sequences. These various sequences of operations are to be included within the scope of embodiments.

At operation 202, processing of a wafer in the first chamber of the semiconductor processing system 100 is completed. At operation 204, the wafer is transferred from the first chamber to the cooling chamber of the semiconductor processing system 100. At operation 206, the temperature of the wafer is detected using non-contact temperature sensors. At operation 208, if the wafer temperature is at or substantially at the target temperature, the wafer is transferred to the second chamber of the semiconductor processing system 100 for further processing (operation 210). However, if the wafer temperature is not at or substantially not at the target temperature, the operation of the semiconductor processing system 100 is paused and temperature settings are checked (operation 212). In some embodiments, a temperature difference (between the wafer and the target) of 20° C. to 40° C. can cause the operation of the semiconductor processing system 100 to be paused, while in other embodiments a temperature difference of 30° C. can cause the operation of the semiconductor processing system 100 to be paused. As appreciated by one of ordinary skill in the art, any suitable temperature difference can be used to pause the operation.

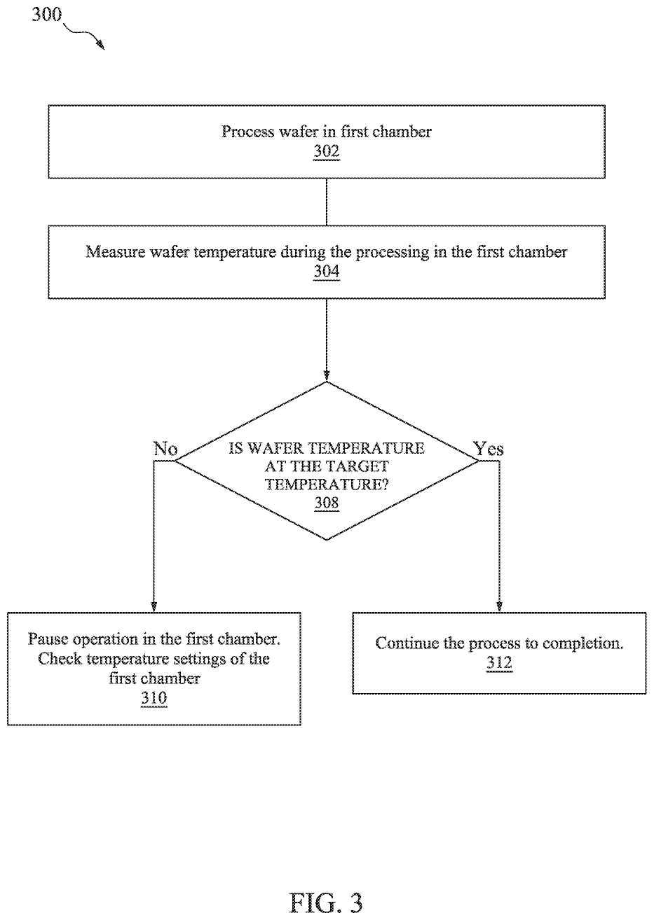

FIG. 3 is a flowchart diagram illustrating an example method 300 in accordance with some embodiments. In the example shown in FIG. 3, the method 300 includes operations 302, 304, 308, 310 and 312. Additional operations may be performed. Also, it should be understood that the sequence of the various operations discussed above with reference to FIG. 3 is provided for illustrative purposes, and as such, other embodiments may utilize different sequences. These various sequences of operations are to be included within the scope of embodiments.

At operation 302, a semiconductor wafer is processed in the first chamber of the semiconductor processing system 100 is completed. At operation 304, the semiconductor wafer temperature is by non-contact temperature sensors during the processing of the semiconductor wafer. At operation 308, if the wafer temperature is at or substantially at the target temperature, the wafer processing is completed (operation 312). However, if the wafer temperature is not at or substantially not at the target temperature, the operation of the semiconductor processing system 100 is paused and temperature settings are checked (operation 310).

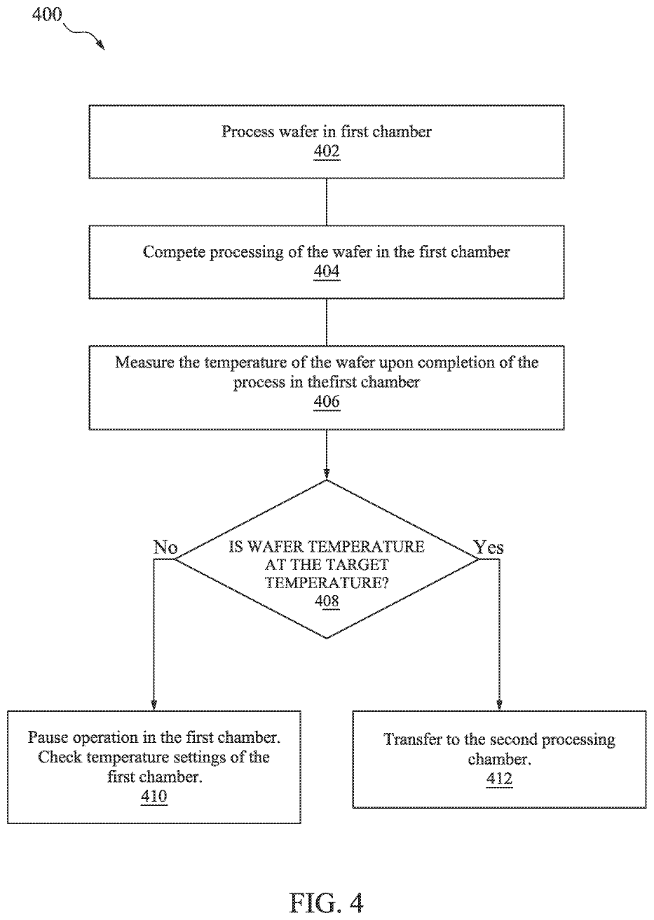

FIG. 4 is a flowchart diagram illustrating an example method 400 in accordance with some embodiments. In the example shown in FIG. 4, the method 400 includes operations 402, 404, 408, 410 and 412. Additional operations may be performed. Also, it should be understood that the sequence of the various operations discussed above with reference to FIG. 4 is provided for illustrative purposes, and as such, other embodiments may utilize different sequences. These various sequences of operations are to be included within the scope of embodiments.

At operation 302, a semiconductor wafer is processed in the first chamber of the semiconductor processing system 100 is completed. At operation 404, the semiconductor wafer processing is completed in the first chamber. At operation 406, non-contact temperature sensors measure the temperature of the semiconductor wafer at various locations such as center, edge and regions in between. At operation 308, if the wafer temperature is at or substantially at the target temperature, the wafer is transferred to the second chamber for further processing (operation 412). However, if the semiconductor wafer temperature is not at or substantially not at the target temperature, the operation of the semiconductor processing system 100 is paused and temperature settings are checked (operation 410).

In some embodiments, the non-contact temperature sensors can be coupled to a temperature adjustment unit with a heating system in the processing chamber. The non-contact temperature sensors can be configured to transmit real time wafer temperature data to the temperature adjustment unit. The real time semiconductor wafer temperature data is transmitted to the temperature adjustment unit, where an output of the heating system can be adjusted accordingly such that the temperature of the semiconductor wafer stays within the target temperature range.

In accordance with some aspects of the disclosure, a semiconductor processing system is provided. The semiconductor processing system includes: a first chamber arranged to perform a first semiconductor process; a second chamber arranged to perform a second semiconductor process; a cooling chamber having a pedestal; and a plurality of non-contact temperature sensors mounted in the cooling chamber, and arranged to measure a temperature of a wafer disposed on the pedestal; wherein the first chamber is arranged to transfer the wafer to the cooling chamber upon completion of the first semiconductor process in the first chamber; and wherein the cooling chamber is arranged to measure the temperature of the wafer in the cooling chamber and arranged to: transfer the wafer to the second chamber when the temperature of wafer is at a target temperature, or pause processing of the wafer when the temperature of the wafer is not at the target temperature.

In accordance with some aspects of the disclosure, a method of operating a semiconductor processing system is provided. The method of operating a semiconductor processing system includes: providing a semiconductor process system having a first chamber, a second chamber and a cooling chamber, the cooling chamber having a plurality of non-contact temperature detectors; performing, in the first chamber, a first semiconductor process on a wafer; transferring the wafer to the cooling chamber; measuring, by the plurality of non-contact temperature detectors, a plurality of temperatures at the wafer in the cooling chamber; generating an average temperature of the wafer by taking an average of the plurality of temperatures; and comparing the average temperature of the wafer to a target temperature.

In accordance with some aspects of the disclosure, a method of operating a semiconductor processing system is provided. The method of operating a semiconductor processing system includes: providing a semiconductor process system having a first chamber and a second chamber, the first chamber having a plurality of non-contact temperature detectors; performing, in the first chamber, a first semiconductor process on a wafer; measuring, by the plurality of non-contact temperature detectors, a temperature of the wafer in the first chamber; and comparing the measured temperature of the wafer to a target temperature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor processing system comprising:
a first chamber arranged to perform a first semiconductor process;
a second chamber arranged to perform a second semiconductor process;
a cooling chamber having a pedestal; and
a plurality of non-contact temperature sensors mounted in the cooling chamber, and arranged to measure a temperature of a wafer disposed on the pedestal;
wherein the first chamber is arranged to transfer the wafer to the cooling chamber upon completion of the first semiconductor process in the first chamber; and
wherein the cooling chamber is arranged to measure the temperature of the wafer in the cooling chamber and arranged to:
transfer the wafer to the second chamber when the temperature of wafer is at a target temperature, or
pause processing of the wafer when the temperature of the wafer is not at the target temperature.

2. The semiconductor processing system of claim 1, wherein sensors of the plurality of non-contact temperature sensors are infrared temperature sensors.

3. The semiconductor processing system of claim 1, wherein sensors of the plurality of non-contact temperature sensors are ultrasonic temperature sensors.

4. The semiconductor processing system of claim 1, wherein the plurality of non-contact temperature sensors is arranged to measure a first temperature in a center region of the wafer, a second temperature in an edge region of the wafer and a third temperature in a region between the center region and the edge region of the wafer.

5. The semiconductor processing system of claim 4, wherein the cooling chamber is arranged to generate the temperature of the wafer by taking an average of the first, second and third temperatures.

6. A method of operating a semiconductor processing system, comprising:
providing a semiconductor process system having a first chamber, a second chamber and a cooling chamber, the cooling chamber having a plurality of non-contact temperature detectors;
performing, in the first chamber, a first semiconductor process on a wafer;
transferring the wafer to the cooling chamber;
measuring, by the plurality of non-contact temperature detectors, a plurality of temperatures at the wafer in the cooling chamber;
generating an average temperature of the wafer by taking an average of the plurality of temperatures; and
comparing the average temperature of the wafer to a target temperature.

7. The method of claim 6, further comprising pausing an operation of the semiconductor processing system if the average temperature of the wafer is not substantially at the target temperature.

8. The method of claim 6, further comprising transferring the wafer from the first chamber to the second chamber if the average temperature of the wafer is at the target temperature.

9. The method of claim 8, further comprising performing, in the second chamber, a second semiconductor process on the wafer.

10. The method of claim 6, wherein the cooling chamber comprises a pedestal arranged to handle the wafer.

11. The method of claim 6, wherein measuring the plurality of temperatures of the wafer comprises measuring a first temperature at a center region of the wafer, a second temperature at an edge region of the wafer and a third temperature at a region between the center region and the edge region of the wafer.

12. The method of claim 6, wherein each of the plurality of non-contact temperature detectors is an infrared temperature detector.

13. The method of claim 6, wherein each of the plurality of non-contact temperature detectors is an ultrasonic temperature detector.

14. A method of operating a semiconductor processing system, comprising:
providing a semiconductor process system having a first chamber and a second chamber, the first chamber having a plurality of non-contact temperature detectors;
performing, in the first chamber, a first semiconductor process on a wafer;
measuring, by the plurality of non-contact temperature detectors, a temperature of the wafer in the first chamber; and
comparing the measured temperature of the wafer to a target temperature.

15. The method of claim 14, further comprising transferring the wafer to the second chamber if the measured temperature of the wafer is at the target temperature.

16. The method of claim 14, further comprising pausing an operation of the semiconductor processing system if the measured temperature of the wafer is not at the target temperature.

17. The method of claim 14, wherein the plurality of non-contact temperature detectors are infrared temperature detectors.

18. The method of claim 14, wherein the plurality of non-contact temperature detectors are ultrasonic temperature detectors.

19. The method of claim 14, wherein measuring the temperature of the wafer comprises detecting a first temperature at a center region of the wafer, a second temperature at an edge region of the wafer and a third temperature at a region between the center region and the edge region of the wafer.

20. The method of claim 19, further comprising generating an average temperature of the wafer by taking an average of the first, second and third temperatures.
